(19) United States
(12) Patent Application Publication
(10) Pub. No.: US 2012/0211078 A1
(43) Pub. Date: Aug. 23, 2012

(54) ORGANIC PHOTOVOLTAIC CELL

(75) Inventors: Takehito Kato, Tochigi (JP); Toshihiro Ohnishi, Ibaraki (JP)

(73) Assignee: Sumitomo Chemical Company, Limited, Tokyo (JP)

(21) Appl. No.: 13/503,864

(22) PCT Filed: Oct. 26, 2010
(86) PCT No.: PCT/JP2010/068947

§ 371 Date: Apr. 25, 2012

(30) Foreign Application Priority Data
Oct. 30, 2009 (JP) 2009-250582

(51) Int. Cl. H01L 31/0232

(52) U.S. Cl. 136/257

(57) ABSTRACT

Provided is an organic photovoltaic cell having a long lifetime. An organic photovoltaic cell 100 comprises a first electrode 2, an active layer 3 capable of generating a charge by incident light, a second electrode 4, and a barrier layer 6 in this order. The barrier layer 6 comprises an inorganic layer 7 comprising an inorganic material and an organic layer 8 comprising an organic material. One or both of the inorganic layer 7 and the organic layer 8 have a function of blocking ultraviolet light.

### TECHNICAL FIELD

The present invention relates to an organic photovoltaic cell.

### BACKGROUND ART

A photovoltaic cell is a cell that can convert light energy into electric energy and an example thereof is a solar cell. The solar cell typically includes a silicon solar cell. However, the silicon solar cell requires a high vacuum environment and a high pressure environment in the production process to increase production cost. On this account, an organic solar cell has been drawing attention because the production cost of the organic solar cell is lower than that of the silicon solar cell.

However, the organic solar cell uses an organic material, which is likely to deteriorate due to ultraviolet light (UV) and the like, and thus the organic solar cell tends to have shorter lifetime than that of the silicon solar cell. Hence, in order to elongate the lifetime of the organic solar cell, various techniques have been developed. For example, Patent Document 1 discloses an organic solar cell that includes an UV cut film in order to block ultraviolet light.

### RELATED ART DOCUMENTS

### Patent Literature

Patent Document 1: JP No. 2007-67115 A

### SUMMARY

The organic solar cell that includes an UV cut film to block incident ultraviolet light can suppress deterioration of the organic material due to the ultraviolet light to elongate the lifetime of the organic solar cell. However, the technique according to Patent Document 1 insufficiently elongates the lifetime; therefore, there has been a demand for techniques that can further elongate the lifetime of the organic solar cell. The aforementioned subject has been also common to organic photovoltaic cells other than the organic solar cell.

In view of the above problems, the present invention provides an organic photovoltaic cell having a longer lifetime.

The inventors of the present invention have carried out intensive studies in order to solve the problems; as a result, they have found that it is possible to elongate the lifetime by protecting an organic photovoltaic cell with a barrier layer comprising an inorganic layer comprising an inorganic material and an organic layer comprising an organic material, and by giving at least one of the inorganic layer and the organic layer a function of blocking ultraviolet light, since the organic photovoltaic cell can be effectively protected from oxygen, water, and ultraviolet light by using characteristics of the inorganic material and the organic material. In this manner, the present invention has been accomplished.

That is, the present invention is as follows.

[1] An organic photovoltaic cell comprising:

a first electrode;

an active layer capable of generating a charge by incident light;

a second electrode; and

a barrier layer, in this order, wherein the barrier layer comprises an inorganic layer comprising an inorganic material and an organic layer comprising an organic material; and

one or both of the inorganic layer and the organic layer have a function of blocking ultraviolet light.

[2] The organic photovoltaic cell according to [1], wherein the organic photovoltaic cell further comprises an ultraviolet absorbing layer, and

the active layer, the first electrode, and the ultraviolet absorbing layer are arranged in this order.

[3] The organic photovoltaic cell according to [1] or [2], wherein the barrier layer comprises the inorganic layer and the organic layer in this order from the second electrode.

### BRIEF DESCRIPTION OF DRAWINGS

FIG. 1 is a schematic cross-sectional view of an organic photovoltaic cell of a first embodiment of the present invention.

FIG. 2 is a schematic cross-sectional view of an organic photovoltaic cell of a second embodiment of the present invention.

### EXPLANATIONS OF LETTERS OR NUMERALS

1 substrate
2 first electrode
3 active layer
4 second electrode
5 ultraviolet absorbing layer
6 barrier layer
7 inorganic layer
8 organic layer
100, 200 organic photovoltaic cell

### DESCRIPTION OF EMBODIMENTS

Hereinafter, the present invention will be described in detail with reference to embodiments, exemplary substances, and the like, but the present invention is not limited thereto, and any changes and modifications may be made in the present invention without departing from the gist of the present invention. In the present invention, “ultraviolet light” refers to light having a wavelength of 400 nm or less.

### 1. OUTLINE

The organic photovoltaic cell of the present invention comprises a first electrode, an active layer capable of generating a charge by incident light, a second electrode, and a barrier layer in this order. Hence, the layers are arranged in the order of the first electrode, the active layer, the second electrode, and the barrier layer. The barrier layer comprises an inorganic layer comprising an inorganic material and an organic layer comprising an organic material. One or both of the inorganic layer and the organic layer have a function of blocking ultraviolet light.

Generally, the inorganic layer and the organic layer can block the penetration of oxygen and water from outside to inside of the organic photovoltaic cell. The organic layer can suppress damage to the first electrode, the second electrode, and the active layer caused by external force from outside of the organic photovoltaic cell. The function of blocking ultraviolet light that one or both of the inorganic layer and the organic layer have can suppress deterioration of organic materials contained in the active layer and the functional layer due to ultraviolet light. Therefore, the organic photovoltaic cell of the present invention can be effectively protected from oxygen, water, ultraviolet light, and external force, and thus can stably maintain photovoltaic conversion characteristics for a long time to elongate the lifetime.

The organic photovoltaic cell of the present invention may further have other layers in addition to the first electrode, the active layer, the second electrode, and a barrier layer. For example, the organic photovoltaic cell of the present invention may have a functional layer between the first electrode and the active layer and may have a functional layer between the active layer and the second electrode.

The organic photovoltaic cell of the present invention usually further comprises a substrate and, on the substrate, layers (for example, the first electrode, the active layer, the second electrode, the barrier layer, and the functional layers) are stacked to constitute the organic photovoltaic cell of the present invention.

### 2. SUBSTRATE

The substrate is a member serving as a support of the organic photovoltaic cell of the present invention. The substrate usually employs a member that is not chemically changed during the formation of the electrodes and the formation of an organic material layer. Examples of a material for the substrate may include glass, a plastic, a polymer film, and silicon. The materials for the substrate may be used alone or in combination of two or more of them at any ratio.

A transparent or translucent member is usually used as the substrate, but an opaque substrate may be used. However, when the opaque substrate is used, the electrode opposite to the opaque substrate (namely, either the first electrode or the second electrode which is the electrode more distant from the opaque substrate) is preferably transparent or translucent.

### 3. FIRST ELECTRODE AND SECOND ELECTRODE

Of the first electrode and the second electrode, one is an anode and the other is a cathode. At least one of the first electrode and the second electrode is preferably transparent or translucent so that light can readily enter the active layer placed between the first electrode and the second electrode. In the organic photovoltaic cell of the present invention, light is usually applied from the second electrode side, and the organic photovoltaic cell can reduce ultraviolet light contained in the light that passes thorough the barrier layer and the second electrode and enter the active layer. Thus, the second electrode is preferably transparent or translucent.

Examples of the transparent or translucent electrode may include an electrically conductive metal oxide film and a translucent metal thin film. Examples of a material for the transparent or translucent electrode may include: films formed using electrically conductive materials such as indium oxide, zinc oxide, tin oxide, complexes of them such as indium tin oxide (ITO), indium zinc oxide (IZO), and NESA; gold; platinum; silver; and copper. Among them, ITO, indium zinc oxide, and tin oxide are preferred.

As the material for the transparent or translucent electrode, an organic material may also be used. Examples of the organic material usable as the material for the electrode may include electrically conductive polymers such as polyaniline, a derivative thereof, polythiophene, and a derivative thereof.

Examples of a material for the opaque electrode may include a metal and an electrically conductive polymer. Specific examples of the material may include: metals such as lithium, sodium, potassium, rubidium, cesium, magnesium, calcium, strontium, barium, aluminum, scandium, vanadium, zinc, yttrium, indium, cerium, samarium, europium, terbium, and ytterbium; an alloy of two or more of the metals; an alloy of one or more of the metals and one or more of metals selected from a group consisting of gold, silver, platinum, copper, manganese, titanium, cobalt, nickel, tungsten, and tin; graphite; a graphite intercalation compound; polyaniline and a derivative thereof; and polythiophene and a derivative thereof. Specific examples of the alloy may include a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy.

The materials for the electrode may be used alone or in combination of two or more of them at any ratio.

Each of the first electrode and the second electrode has a varied thickness depending on the material type of the electrode. The thickness is preferably 500 nm or smaller and more preferably 200 nm or smaller in order to increase transmittance of light and to suppress electric resistance. The thickness has no lower limit but is usually 10 nm or larger.

Examples of the formation method of the first electrode and the second electrode may include a vacuum deposition method, a sputtering method, an ion plating method, and a plating method. For the formation of the first electrode and the second electrode from, for example, an electrically conductive polymer, a coating method may be employed.

### 4. ACTIVE LAYER

The active layer is a layer capable of generating a charge by incident light and usually comprises a p-type semiconductor that is an electron-donor compound and an n-type semiconductor that is an electron-acceptor compound. The organic photovoltaic cell of the present invention uses an organic compound as at least one of the p-type semiconductor and the n-type semiconductor, usually as both semiconductors, and hence is called the “organic” photovoltaic cell. The p-type semiconductor and the n-type semiconductor are relatively determined by the energy level of each energy state of the semiconductors.

In the active layer, the charge is supposed to be generated in the following manner. When light energy input to the active layer is absorbed in one or both of the n-type semiconductor and the p-type semiconductor, an exinton comprising an electron and a hole bonded to each other is formed. The formed exciton is transferred to reach to a heterojunction interface where the n-type semiconductor is in contact with the p-type semiconductor. The electron and hole are separated due to corresponding differences of the HOMO (highest occupied molecular orbital) energies and the LUMO (lowest unoccupied molecular orbital) energies at the heterojunction interface, thus generating charges (electron and hole) that can independently move. The generated charges are transferred to the corresponding electrodes to be able to be extracted from the organic photovoltaic cell of the present invention as electric energy (current) to the exterior.

The active layer may have a single layer structure comprising one layer alone or may have a stacked structure comprising two or more layers as long as the active layer can generate a charge by incident light. Examples of the layer composition of the active layer include the following compositions. However, the layer composition of the active layer is not limited to the examples.

Layer composition (i): the active layer having a stacked structure comprising a layer comprising the p-type semiconductor and a layer comprising the n-type semiconductor.

Layer composition (ii): the active layer having a single layer structure comprising the p-type semiconductor and the n-type semiconductor.

Layer composition (iii): the active layer having a stacked structure comprising a layer comprising the p-type semiconductor, a layer comprising the p-type semiconductor and the n-type semiconductor, and a layer comprising the n-type semiconductor.

Examples of the p-type semiconductor may include a pyrazoline derivative, an arylamine derivative, a stilbene derivative, a triphenyldiamine derivative, oligothiophene and a derivative thereof, polyvinylcarbazole and a derivative thereof, polysilane and a derivative thereof, a polysiloxane derivative having an aromatic amine on a side chain or the main chain, polyaniline and a derivative thereof, polythiophene and a derivative thereof, polypyrrole and a derivative thereof, poly(phenylene vinylene) and a derivative thereof, and poly(thienylene vinylene) and a derivative thereof.

An organic macromolecular compound having a structural unit represented by the following structural formula (1) is preferred as the p-type semiconductor.

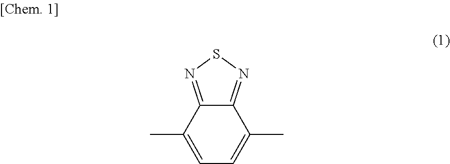

The organic macromolecular compound is more preferably a copolymer of the compound having the structural unit represented by the structural formula (1) and a compound represented by the following structural formula (2).

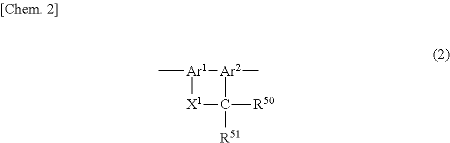

[In Formula (2), Ar¹ and Ar² are the same as or different from each other and represent a trivalent heterocyclic group. X¹ represents —O—, —S—, —C(═O)—, —S(═O)—, —SO₂—, —Si(R³)(R⁴)—, —N(R⁵)—, B(R⁶)—, —P(R⁷)—, or —P(═O)(R⁸)—. R³, R⁴, R⁵, R⁶, R⁷, and R⁸ are the same as or different from each other and represent a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group, or a cyano group. R⁵⁰ represents a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group, or a cyano group. R⁵¹ represents an alkyl group having six or more carbon atoms, an alkyloxy group having six or more carbon atoms, an alkylthio group having six or more carbon atoms, an aryl group having six or more carbon atoms, an aryloxy group having six or more carbon atoms, an arylthio group having six or more carbon atoms, an arylalkyl group having seven or more carbon atoms, an arylalkyloxy group having seven or more carbon atoms, an arylalkylthio group having seven or more carbon atoms, an acyl group having six or more carbon atoms, or an acyloxy group having six or more carbon atoms. X¹ and Ar² are bonded to vicinal positions of the heterocyclic ring comprised in Ar¹, and C(R⁵⁰)(R⁵¹) and Ar¹ are bonded to vicinal positions of the heterocyclic ring comprised in Ar².]

The p-type semiconductors may be used alone or in combination of two or more of them at any ratio.

Examples of the n-type semiconductor may include an oxadiazole derivative, anthraquinodimethane and a derivative thereof, benzoquinone and a derivative thereof, naphthoquinone and a derivative thereof, anthraquinone and a derivative thereof, tetracyanoanthraquinodimethane and a derivative thereof, a fluorenone derivative, diphenyldicyanoethylene and a derivative thereof, a diphenoquinone derivative, metal complexes of 8-hydroxyquinoline and a derivative thereof, polyquinoline and a derivative thereof, polyquinoxaline and a derivative thereof, polyfluorene and a derivative thereof, fullerenes such as C₆₀ and a derivative thereof, a phenanthrene derivative such as bathocuproine, a metal oxide such as titanium dioxide, and a carbon nanotube. Among them, titanium dioxide, a carbon nanotube, a fullerene, and a fullerene derivative are preferred, and a fullerene and a fullerene derivative are especially preferred.

Examples of the fullerene may include C₆₀ fullerene, C₇₀ fullerene, C₇₆ fullerene, C₇₈ fullerene, and C₈₄ fullerene.

Examples of the fullerene derivative may include derivatives of C₆₀, C₇₀, C₇₆, C₇₈, and C₈₄. Specific examples of the fullerene derivative may include compounds having the following structures.

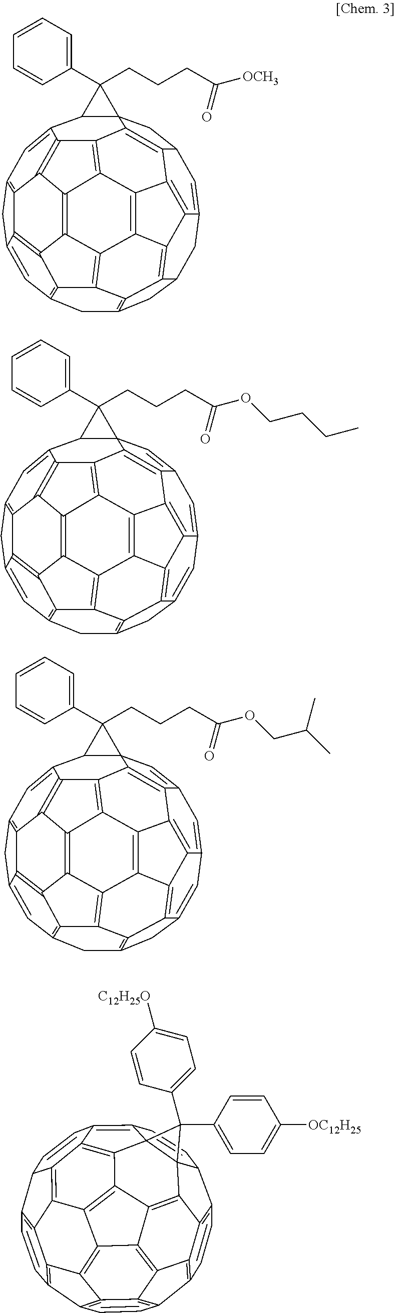

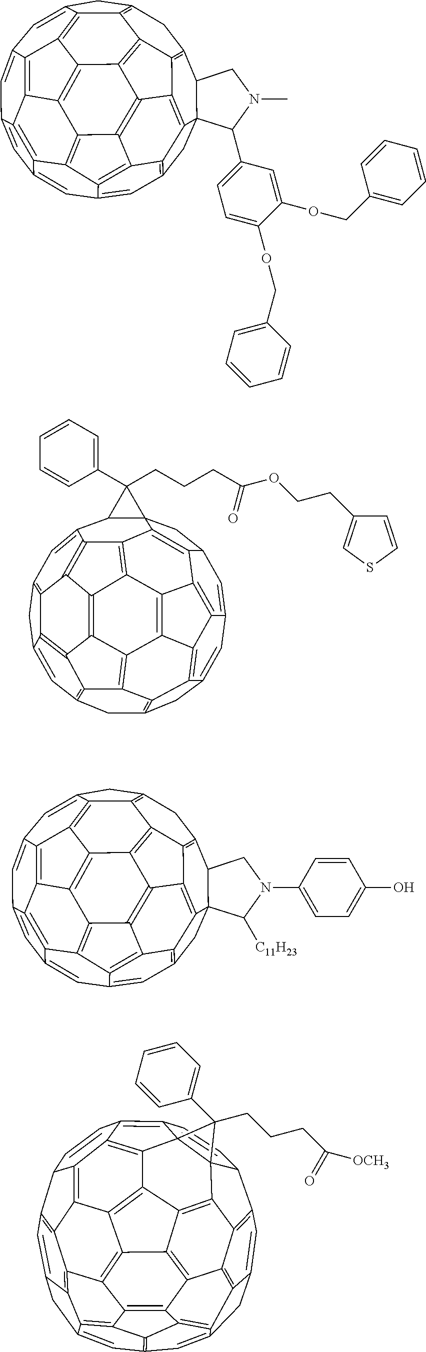

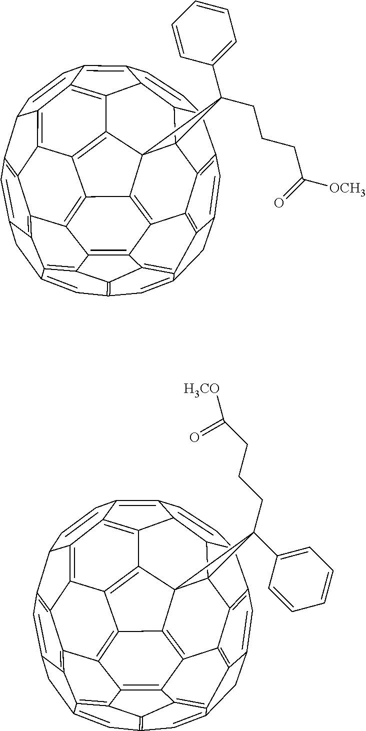

Other examples of the fullerene derivative may include [6,6]-phenyl C₆₁ butyric acid methyl ester (C60PCBM), [6,6]-phenyl C₇₁ butyric acid methyl ester (C70PCBM), [6,6]-phenyl C₈₅ butyric acid methyl ester (C84PCBM), and [6,6]-thienyl C₆₁ butyric acid methyl ester.

The n-type semiconductors may be used alone or in combination of two or more of them at any ratio.

The active layer may comprise the p-type semiconductor and the n-type semiconductor at any ratio as long as the effect of the present invention is not impaired. For example, in a layer comprising both of the p-type semiconductor and the n-type semiconductor in the layer compositions (i) and (iii), the n-type semiconductor is preferably comprised in an amount of 10 parts by weight or more and more preferably 20 parts by weight or more, and is preferably comprised in an amount of 1,000 parts by weight or less and more preferably 500 parts by weight or less, with respect to 100 parts by weight of the p-type semiconductor.

The active layer usually has a thickness of 1 nm or larger, preferably 2 nm or larger, more preferably 5 nm or larger, and particularly preferably 20 nm or larger, and usually has a thickness of 100 μm or smaller, preferably 1,000 nm or smaller, more preferably 500 nm or smaller, and particularly preferably 200 nm or smaller.

The active layer may be formed by any method. Examples of the method may include a film formation method from a liquid composition comprising a material (for example, one or both of the p-type semiconductor and the n-type semiconductor) for the active layer; and a film formation method by a gas phase film formation method such as a physical vapor deposition method (PVD method) including a vacuum deposition method and a chemical vapor deposition method (CVD method). Among them, the film formation method from a liquid composition is preferred because a film is readily formed to reduce the cost.

In the film formation method from a liquid composition, a liquid composition is prepared, the liquid composition is applied onto a desired area to form a film as the active layer.

The liquid composition usually comprises a material for the active layer and a solvent. When the solvent is contained, the liquid composition may be a dispersion liquid dispersing the material for the active layer in the solvent, but is preferably a solution dissolving the material for the active layer in the solvent. Hence, the solvent to be used is preferably a solvent that can dissolve the material for the active layer. Examples of the solvent may include unsaturated hydrocarbon solvents such as toluene, xylene, mesitylene, tetralin, decalin, bicyclohexyl, n-butylbenzene, sec-butylbenzene, and tert-butylbenzene; halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, and bromocyclohexane; halogenated unsaturated hydrocarbon solvents such as chlorobenzene, dichlorobenzene, and trichlorobenzene; and ether solvents such as tetrahydrofuran and tetrahydropyran. The solvents may be used alone or in combination of two or more of them at any ratio.

Each concentration of the p-type semiconductor and the n-type semiconductor in the liquid composition is usually adjusted to 0.1% by weight or more with respect to a solvent.

Examples of the film formation method of the liquid composition may include coating methods such as a spin coating method, a casting method, a micro-gravure coating method, a gravure coating method, a bar coating method, a roll coating method, a wire bar coating method, a dip coating method, a spray coating method, a screen printing method, a gravure printing method, a flexographic printing method, an offset printing method, an inkjet printing method, a dispenser printing method, a nozzle coating method, and a capillary coating method. Among them, a spin coating method, a flexographic printing method, a gravure printing method, an inkjet printing method, and a dispenser printing method are preferred.

After the film formation of the liquid composition, as necessary, a process such as a process of drying the formed film to remove the solvent is performed, and consequently the active layer is obtained.

For an active layer having a stacked structure comprising two or more layers, for example, each layer constituting the active layer may be sequentially stacked by the aforementioned method.

### 5. FUNCTIONAL LAYER

The organic photovoltaic cell of the present invention may comprise functional layers between the first electrode and the active layer and between the second electrode and the active layer. The functional layer is a layer that can transport the charge generated in the active layer to the electrode. The functional layer between the first electrode and the active layer can transport the charge generated in the active layer to the first electrode, while the functional layer between the second electrode and the active layer can transport the charge generated in the active layer to the second electrode. The functional layer may be provided either between the first electrode and the active layer or between the second electrode and the active layer, and the functional layers may be provided both between the first electrode and the active layer and between the second electrode and the active layer.

The functional layer provided between the active layer and an anode can transport a hole generated in the active layer to the anode, and is also called a hole transport layer or an electron block layer. Meanwhile, the functional layer provided between the active layer and a cathode can transport an electron generated in the active layer to the cathode, and is also called an electron transport layer or a hole block layer. The effective photovoltaic cell of the present invention that comprises the functional layers can increase extraction efficiency of the hole generated in the active layer to the anode, can increase extraction efficiency of the electron generated in the active layer to the cathode, can suppress transfer of the hole generated in the active layer to the cathode, and can suppress transfer of the electron generated in the active layer to the anode. Consequently, the photovoltaic conversion efficiency can be improved.

The functional layer may comprise a material that can transport the charge generated in the active layer. Specifically, the functional layer between the active layer and the anode preferably comprises a material that can transport the hole and that can suppress the transfer of the electron to the functional layer. The functional layer between the active layer and the cathode preferably comprises a material that can transport the electron and that can suppress the transfer of the hole to the functional layer.

Examples of the material for the functional layer may include: halides and oxides of an alkali metal or an alkaline earth metal, such as lithium fluoride; inorganic semiconductors such as titanium dioxide; bathocuproine, bathophenanthroline and a derivative thereof; a triazole compound; a tris(8-hydroxyquinolinate) aluminum complex; a bis(4-methyl-8-quinolinate) aluminum complex; an oxadiazole compound; a distyrylarylene derivative; a silole compound; a 2,2′,2″-(1,3,5-benzenetolyl)-tris-[1-phenyl-1H-benzimidazole] (TPBI) phthalocyanine derivative; a naphthalocyanine derivative; a porphyrin derivative; aromatic diamine compounds such as N,N′-bis(3-methylphenyl)-(1,1′-biphenyl)-4,4′-diamine (TPD) and 4,4′-bis[N-(naphthyl)-N-phenyl-amino]biphenyl (α-NPD); oxazole; oxadiazole; triazole; imidazole; imidazolone; a stilbene derivative; a pyrazoline derivative; tetrahydroimidazole; polyarylalkane; butadiene; 4,4′,4″-tris(N-(3-methylphenyl)-N-phenylamino)triphenylamine (m-MTDATA); polyvinylcarbazole; polysilane; and poly(3,4-ethylenedioxidethiophene) (PEDOT). The materials may be used alone or in combination of two or more of them at any ratio.

The functional layer may contain other components in addition to the aforementioned materials as long as the effect of the present invention is not significantly impaired.

The other components may be used alone or in combination of two or more of them at any ratio.

The functional layer usually has a thickness of 0.01 nm or larger, preferably 0.1 nm or larger, and more preferably 1 nm or larger, and usually has a thickness of 1,000 nm or smaller, preferably 500 nm or smaller, and more preferably 100 nm or smaller. The functional layer having an excessively small thickness may insufficiently exert the functions of the functional layer, while the functional layer having an excessively large thickness may excessively increase the thickness of the organic photovoltaic cell.

The functional layer may be formed, for example, by a gas phase film formation method, but is preferably formed through a process of applying a liquid composition comprising the material for the functional layer onto a predetermined area because the layer is readily formed to reduce the cost. The method for forming the functional layer from the liquid composition will be described below.

The liquid composition for forming the functional layer usually comprises a material for the functional layer and a solvent. When the solvent is contained, the liquid composition may be a dispersion liquid dispersing the material for the functional layer in the solvent and may be a solution dissolving the material for the functional layer in the solvent.

Examples of the solvent contained in the liquid composition for forming the functional layer may include solvents similar to the solvents contained in the liquid composition for forming the active layer. The solvents may be used alone or in combination of two or more of them at any ratio.

In the liquid composition, the solvent is usually contained in an amount of 10 parts by weight or more, preferably 50 parts by weight or more, and more preferably 100 parts by weight or more, and is usually contained in an amount of 100,000 parts by weight or less, preferably 10,000 parts by weight or less, and more preferably 5,000 parts by weight or less, with respect to 100 parts by weight of the material for the functional layer.

After the preparation of the liquid composition for forming the functional layer, the liquid composition is applied onto a predetermined area where the functional layer is intended to be formed. Usually, the liquid composition is applied onto a layer (usually, the first electrode, the second electrode, or the active layer) to be in contact with the functional layer in the organic photovoltaic cell of the present invention. Examples of the coating method of the liquid composition may include coating methods similar to the coating methods of the liquid composition for forming the active layer.

The liquid composition for forming the functional layer is applied to form a film comprising the material for the functional layer. Thus, after the application of the liquid composition, as necessary, a process such as a process of drying the formed film to remove the solvent is performed, and consequently the functional layer is obtained.

### 6. BARRIER LAYER

The barrier layer is a layer that comprises at least one inorganic layer and at least one organic layer. The barrier layer that comprises the inorganic layer and the organic layer can usually block the penetration of oxygen and water from outside of the organic photovoltaic cell.

The organic photovoltaic cell transfers charges through surfaces of the first electrode and the second electrode. Thus, a chemically changed electrode surface interferes with the charge transfer. In particular, oxidation of the electrode is supposed to be one of main factors contributing to the deterioration of the organic photovoltaic cell. The oxidation of the electrode is likely to be caused by a reaction of oxygen and water with the electrode. Hence, the removal of oxygen and water (especially water) can elongate lifetime of the organic photovoltaic cell. In the organic photovoltaic cell of the present invention, usually the barrier layer blocks the penetration of oxygen and water from outside of the organic photovoltaic cell to protect the first electrode and the second electrode (specifically, the second electrode). On this account, the organic photovoltaic cell of the present invention can maintain the photovoltaic conversion efficiency for a longer time than that of a conventional cell to elongate lifetime of the organic photovoltaic cell.

In the barrier layer, one or both of the inorganic layer and the organic layer have a function of blocking ultraviolet light. An organic material contained in the active layer and the like is likely to reduce light absorbing ability due to photooxidation when such a material is irradiated with ultraviolet light in the presence of oxygen. However, the ultraviolet light is blocked by one or both of the inorganic layer and the organic layer to suppress the photooxidation. The barrier layer also has the function of blocking oxygen and water as described above. Hence, the amount of oxygen itself in the cell can be reduced to suppress the photooxidation.

The barrier layer is usually provided so as to cover at least a part of the surface of the organic photovoltaic cell, and consequently can protect the covered area from water, oxygen, ultraviolet light, and the like. Furthermore, the barrier layer usually covers at least the second electrode from the outside, and consequently can especially increase sealing properties of the second electrode.

When light is applied from a side closer to the second electrode than the active layer to the organic photovoltaic cell, the applied light is input through the barrier layer to the active layer. Light that has not been used for photovoltaic conversion in the active layer is reflected off the first electrode and then is input to the barrier layer. Hence, the barrier layer that causes light scattering and the like can trap light in the organic photovoltaic cell to increase the photovoltaic conversion efficiency.

### 6-1. Inorganic Layer

The inorganic layer is a layer that comprises an inorganic material. The inorganic material is likely to have excellent anti-moisture permeability and anti-oxygen permeability. Thus, the inorganic layer that is provided in the barrier layer can block the penetration of oxygen and water to the inside of the organic photovoltaic cell of the present invention to suppress the action of oxygen and water from outside to the organic photovoltaic cell.

The inorganic layer preferably contains an inorganic material that has high anti-moisture permeability and high anti-oxygen permeability and that is stable with respect to water such as water vapor. Examples of the inorganic material may include silicon compounds such as silicon oxide, silicon nitride, silicon oxynitride, and silicon carbide; aluminum compounds such as aluminum oxide, aluminum nitride, and aluminum silicate; metal oxides such as zirconium oxide, tantalum oxide, and titanium oxide; metal nitrides such as titanium nitride; and diamond-like carbon. Among them, silicon compounds such as silicon nitride, silicon oxide, silicon oxynitride, and silicon carbide; aluminum compounds such as aluminum oxide, aluminum nitride, and aluminum silicate; zirconium oxide; tantalum oxide; titanium oxide; and titanium nitride are preferred. Among the inorganic materials, an amorphous (noncrystalline) material is specifically preferred because it has small water permeability.

The inorganic materials may be used alone or in combination of two or more of them at any ratio.

When the inorganic layer has a function of blocking ultraviolet light, the inorganic layer usually contains an ultraviolet absorber that is a material capable of absorbing ultraviolet light. The ultraviolet absorber absorbs ultraviolet light contained in light that is applied to the organic photovoltaic cell of the present invention to block ultraviolet light as much as at least the absorbed ultraviolet light, and consequently can suppress the deterioration of organic materials contained in the active layer, the functional layer, and the like due to ultraviolet light.

For the ultraviolet absorber, examples of the organic material may include benzophenone ultraviolet absorbers, benzotriazole ultraviolet absorbers, triazine ultraviolet absorbers, and phenyl salicylate ultraviolet absorbers. Among them, preferred examples specifically may include 2,4-dihydroxy-benzophenone, 2-hydroxy-4-methoxybenzophenone, 4-dodecyloxy-2-hydroxybenzophenone, 2-hydroxy-4-methoxy-5-sulfobenzophenone, 2-(2′-hydroxy-5-methylphenyl)benzotriazole, 2-(2′-hydroxy-3′,5′-di-tert-butylphenyl)benzotriazole, phenyl salicylate, p-octylphenyl salicylate, and p-tert-butylphenyl salicylate. Examples of the ultraviolet absorber composed of the inorganic material may include titanium dioxide and zinc oxide.

As the ultraviolet absorber, a wavelength-conversion material that can perform wavelength-conversion of absorbed ultraviolet light into light having a longer wavelength than that of the absorbed ultraviolet light may be used. When the wavelength-conversion material is used as at least some of the ultraviolet absorber, the light that has subjected to wavelength-conversion and that has a longer wavelength is input to the active layer to be used as the light energy for charge generation in the active layer. Thus, the use of the wavelength-conversion material as the ultraviolet absorber can reduce ultraviolet light input to the active layer to suppress the deterioration of an organic material as well as can increase the charge generation amount in the active layer to improve the photovoltaic conversion efficiency. Examples of the light that has been subjected to wavelength-conversion from the absorbed ultraviolet light may include visible light, near infrared light, and infrared light. A wavelength-conversion material capable of wavelength-conversion of the ultraviolet light into the visible light is preferred in order to increase the photovoltaic conversion efficiency.

Examples of the wavelength-conversion material may include a phosphor. The phosphor is usually a material that can absorb excitation light to emit fluorescence having longer wavelength than that of the excitation light. Hence, for the phosphor used as the ultraviolet absorber, a phosphor capable of absorbing ultraviolet light as the excitation light and capable of emitting fluorescence having such wavelength available for the charge generation in the active layer may be used.

Among the phosphors, examples of the organic phosphor may include a rare earth complex. The rare earth complex is a phosphor excellent in fluorescent characteristics, and specific examples may include a [Tb(bpY)₂]Cl₃ complex, an [Eu(phen)₂]Cl₃ complex, and a [Tb(terpy)₂]Cl₃ complex. Here, “bpy” represents 2,2-bipyridine, “phen” represents 1,10-phenanthroline, and “terpy” represents 2,2′:6′,2″-terpyridine. Examples of the inorganic phosphor may include MgF₂:Eu²⁺ (an absorption wavelength of 300 nm to 400 nm, a fluorescence wavelength of 400 nm to 550 nm), 1.29(Ba, Ca)O-6Al₂O₃:Eu²⁺ (an absorption wavelength of 200 nm to 400 nm, a fluorescence wavelength of 400 nm to 600 nm), BaAl₂O₄:Eu²⁺ (an absorption wavelength of 200 nm to 400 nm, a fluorescence wavelength of 400 nm to 600 nm), and Y₃Al₅O₁₂:Ce³⁺ (an absorption wavelength of 250 nm to 450 nm, a fluorescence wavelength of 500 nm to 700 nm).

The ultraviolet absorbers may be used alone or in combination of two or more of them at any ratio.

However, as the ultraviolet absorber contained in the inorganic layer, an ultraviolet absorber composed of an inorganic material is preferably used. This is because such an inorganic layer can sufficiently exert the function of blocking water and oxygen.

In the inorganic layer, the ultraviolet absorber is usually contained at a ratio of 3% by weight or more and 100% by weight or less, preferably 10% by weight or more and 100% by weight or less, and more preferably 25% by weight or more and 100% by weight or less in order to block a sufficient amount of ultraviolet light.

The inorganic layer may include other components in addition to the inorganic material as long as the effect of the present invention is not significantly impaired. Examples of the other components may include a binder such as a resin, a getter agent (oxygen adsorbent and water adsorbent) such as an alkoxide, a surfactant, a dispersant, and an antioxidant. The other components may be used alone or in combination of two or more of them at any ratio.

In the inorganic layer, the inorganic material is usually contained at a ratio of 3% by weight or more and 100% by weight or less, preferably 10% by weight or more and 100% by weight or less, and more preferably 25% by weight or more and 100% by weight or less in order to stably exert the function of the inorganic layer.

The inorganic layer preferably has a thickness of 1 μm or larger, more preferably 3 μm or larger, and particularly preferably 5 μm or larger. The inorganic layer having such a thickness can increase the sealing properties of the organic photovoltaic cell to stably block oxygen and water. For the inorganic layer, the thickness of has no upper limit, but is usually 10 μm or smaller from the viewpoints of the productivity, the cost, and the like.

Examples of the method for forming the inorganic layer may include a gas phase film formation method such as a physical vapor deposition method (PVD method) and a chemical vapor deposition method (CVD method) (see “Thin Film Handbook” edited by Japan Society for the Promotion of Science, 131st Committee (Thin Film), (Ohmsha, Ltd.)). The gas phase film formation method is a deposition method at a molecular level. Hence, the method can form an inorganic layer achieving excellent adhesion to an adjacent layer and can form a high quality inorganic layer that can stably block the penetration of oxygen and water from an interface.

The inorganic layer may also be formed, for example, by a coating method. The coating method is an economically advantageous method because a layer can be readily formed to reduce the cost. When the inorganic layer is formed by the coating method, a liquid composition comprising the inorganic material is firstly prepared, and a coating process of applying the prepared liquid composition onto a desired area is carried out to form the inorganic layer.

The liquid composition for forming the inorganic layer usually comprises materials (the inorganic material; and an ultraviolet absorber and other components contained as necessary) for the inorganic layer and a solvent. When the solvent is contained, the liquid composition may be a dispersion liquid dispersing the material for the inorganic layer in the solvent and may be a solution dissolving the material for the inorganic layer in the solvent.

Examples of the solvent contained in the liquid composition for forming the inorganic layer may include solvents similar to the solvents contained in the liquid composition for forming the active layer. The solvents may be used alone or in combination of two or more of them at any ratio.

In the liquid composition, the solvent is usually contained in an amount of 10 parts by weight or more, preferably 50 parts by weight or more, and more preferably 100 parts by weight or more and is usually contained in an amount of 100,000 parts by weight or less, preferably 10,000 parts by weight or less, and more preferably 5,000 parts by weight or less, with respect to 100 parts by weight of the inorganic material.

After the preparation of the liquid composition for forming the inorganic layer, the liquid composition is applied onto a desired area where the inorganic layer is intended to be formed. Usually, the liquid composition is applied so as to cover a surface of the organic photovoltaic cell. Examples of the coating method of the liquid composition may include coating methods similar to the coating methods of the liquid composition for forming the active layer.

The liquid composition for forming the inorganic layer is applied to form a film comprising the inorganic material. Thus, after the application of the liquid composition, as necessary, a process such as a process of drying the formed film to remove the solvent is performed, and consequently the inorganic layer is obtained.

### 6-2. Organic Layer

The organic layer is a layer containing an organic material. The organic material has excellent flexibility as compared with an inorganic material. Thus, the organic layer that is provided in the barrier layer can suppress the damage to the organic photovoltaic cell caused by external force from outside of the organic photovoltaic cell to the first electrode, the active layer, and the second electrode. The arrangement of the organic layer can increase the oxygen and water blocking performance in comparison with the arrangement of the inorganic layer alone.

The organic layer is preferably arranged so that the inorganic layer and the organic layer in the barrier layer would be arranged in the order of the inorganic layer and the organic layer from the second electrode. The organic layer has characteristics that water is unlikely to penetrate as compared with the inorganic layer. Thus, the arrangement of the organic layer on an outer side of the inorganic layer can effectively suppress the penetration of water into the organic photovoltaic cell. Usually, the inorganic material has poor flexibility and thus is likely to cause defects and the like during the formation of the inorganic layer. Hence, oxygen and water may readily penetrate through the defects and the like. The arrangement of the organic layer on an outside of the inorganic layer can cover the defects and the like in the inorganic layer with the organic material to increase the oxygen and water blocking performance.

As the organic material contained in the organic layer, a resin is preferably used. As the resin, various resins such as a thermosetting resin, a thermoplastic resin, and a photocurable resin may be use, and among them, a photocurable resin is preferred. This is because the organic photovoltaic cell does not deteriorate due to heat during the formation of the organic layer. Preferred examples of the resin may include a silicone resin, an epoxy resin, a fluorine resin, and a wax. The organic materials may be used alone or in combination of two or more of them at any ratio.

When the organic layer has a function of blocking ultraviolet light, the organic layer usually contains an ultraviolet absorber. Examples of the ultraviolet absorber may include ultraviolet absorbers similar to examples of the ultraviolet absorbers cited in the description of the inorganic layer. The organic layer may use a wavelength-conversion material as the ultraviolet absorber as with the inorganic layer.

However, as the ultraviolet absorber contained in the organic layer, an ultraviolet absorber composed of an organic material is preferably used. This is because such an organic layer is allowed to sufficiently exert the functions of blocking water and oxygen and suppressing the damage due to external force.

When the organic layer contains the ultraviolet absorber, the control of the amount of the ultraviolet absorber contained can lead the organic layer to have a controlled refractive index. The organic layer having a properly controlled refractive index can make light reflect off an interface between the organic layer and another layer that is in contact with the organic layer to trap the light in the organic photovoltaic cell; consequently, it is possible to increase the photovoltaic conversion efficiency.

In the organic layer, the ultraviolet absorber is usually contained at a ratio of 50% by weight or more and 100% by weight or less, preferably 75% by weight or more and 100% by weight or less, and more preferably 80% by weight or more and 100% by weight or less in order to block a sufficient amount of ultraviolet light.

The organic layer may include an inorganic material as long as the effect of the present invention is not significantly impaired. In the organic layer, the organic material is usually contained at a ratio of 50% by weight or more and 100% by weight or less, preferably 75% by weight or more and 100% by weight or less, and more preferably 90% by weight or more and 100% by weight or less in order to stably exert the functions of the organic layer.

The organic layer preferably has a thickness of 1 μm or larger and more preferably 5 μm or larger. The organic layer having such a thickness can stably exert the function of blocking oxygen and water. The upper limit of the thickness of the organic layer is usually 100 μm or smaller and preferably 10 μm or smaller. The organic layer having an excessively large thickness may be likely to cause defects such as pinholes, voids, and cracks in the organic layer and may cause cracks by thermal expansion of the organic layer when the organic photovoltaic cell is heated.

Examples of the method for forming the organic layer may include a gas phase film formation method, a coating method, and a method of bonding a previously formed film substance. Among them, the organic layer is preferably formed by the coating method because the layer can be readily formed to reduce the cost.

For example, when the organic layer is formed from a resin as the material by a coating method, a fluid resin is firstly prepared, and a coating process of applying the prepared resin onto a predetermined area is carried out to form the organic layer. The resin may contain a component that is not eventually contained in the organic layer, such as a solvent for controlling viscosity.

After the preparation of the fluid resin, the resin is applied. Examples of the coating method of the resin may include coating methods similar to the coating methods of the liquid composition for forming the active layer.

The resin is applied to form a film of the resin, and, as necessary, a solvent is dried or the resin is cured by light or heat to form the organic layer.

### 6-3. Other Items Relating to Barrier Layer

The barrier layer may include other layers in addition to the inorganic layer and the organic layer as long as the effect of the present invention is not significantly impaired.

In the barrier layer, the inorganic layer and the organic layer are not required to be in contact with each other, but are preferably in contact with each other. Usually, the inorganic layer has a refractive index different from that of the organic layer; hence, an interface where both are in contact with each other is a face that is likely to reflect light. Thus, when the inorganic layer is in contact with the organic layer, light internally reflects off the interface. Consequently, light that is applied to the organic photovoltaic cell of the present invention is trapped in the cell; therefore, it is possible to increase the photovoltaic conversion efficiency.

In the barrier layer, one inorganic layer and one organic layer may be provided and two or more of the inorganic layer and two or more of the organic layer may be provided.

### 7. ULTRAVIOLET ABSORBING LAYER

The organic photovoltaic cell of the present invention preferably comprises an ultraviolet absorbing layer that can block ultraviolet light on a side of the first electrode opposite to the active layer. That is, the organic photovoltaic cell of the present invention preferably comprises the ultraviolet absorbing layer, the first electrode, the active layer, the second electrode, and the barrier layer, in this order. The organic photovoltaic cell having such a structure can block ultraviolet light contained not only in light applied from the second electrode side on which the barrier layer is provided but also in light applied from the first electrode side by the ultraviolet absorbing layer, and consequently can more stably suppress the deterioration of organic materials due to ultraviolet light.

The ultraviolet absorbing layer usually comprises an ultraviolet absorber. Examples of the ultraviolet absorber may include ultraviolet absorbers similar to examples of the ultraviolet absorbers cited in the description of the inorganic layer.

The ultraviolet absorbers may be used alone or in combination of two or more of them at any ratio.

As necessary, the ultraviolet absorbing layer may comprise a binder in order to hold the ultraviolet absorber. A preferred binder is a material that can hold the ultraviolet absorber in the ultraviolet absorbing layer without significantly impairing the effect of the present invention, and a resin is usually used. Examples of the resin usable as the binder may include a polyester resin, an epoxy resin, an acrylic resin, and a fluorine resin. The binders may be used alone or in combination of two or more of them at any ratio.

The binder is usually used in an amount of 3 parts by weight or more, preferably 5 parts by weight or more, and more preferably 10 parts by weight or more, and is usually used in an amount of 80 parts by weight or less, preferably 50 parts by weight or less, and more preferably 30 parts by weight or less, with respect to 100 parts by weight of the ultraviolet absorber. The ultraviolet absorbing layer using the binder in an excessively small amount may unstably hold the ultraviolet absorber, while the ultraviolet absorbing layer using the binder in an excessively large amount may insufficiently block the ultraviolet light.

The ultraviolet absorbing layer may contain other components in addition to the ultraviolet absorber and the binder as long as the effect of the present invention is not significantly impaired. As examples of the other component, additives such as a filler and an antioxidant may be included.

The other components may be used alone or in combination of two or more of them at any ratio.

The ultraviolet absorbing layer usually have a thickness of 1 μm or larger, preferably 10 μm or larger, and more preferably 100 μm or larger, and usually have a thickness of 10,000 μm or smaller, preferably 5,000 μm or smaller, and more preferably 3,000 μm or smaller. The ultraviolet absorbing layer having an excessively small thickness may insufficiently block the ultraviolet light, while the ultraviolet absorbing layer having an excessively large thickness may excessively increase the thickness of the organic photovoltaic cell.

The organic photovoltaic cell of the present invention may comprise one ultraviolet absorbing layer and may comprise two or more layers.

As examples of the method for forming the ultraviolet absorbing layer, a gas phase film formation method, a coating method, and a method of bonding a previously formed film substance may be included. Among them, the ultraviolet absorbing layer are preferably formed by the coating method because the layers can be readily formed to reduce the cost.

In the coating method, applying a liquid composition comprising the ultraviolet absorber onto a predetermined area is carried out to form the ultraviolet absorbing layer.

The liquid composition for forming the ultraviolet absorbing layer usually comprises materials for the ultraviolet absorbing layer, such as the ultraviolet absorber and the binder contained as necessary, and a solvent. When the solvent is contained, the liquid composition may be a dispersion liquid dispersing the material for the ultraviolet absorbing layer in the solvent and may be a solution dissolving the material for the ultraviolet absorbing layer in the solvent.

Examples of the solvent contained in the liquid composition for forming the ultraviolet absorbing layer may include solvents similar to the solvents contained in the liquid composition for forming the active layer. The solvents may be used alone or in combination of two or more of them at any ratio.

In the liquid composition, the solvent is usually contained in an amount of 10 parts by weight or more, preferably 50 parts by weight or more, and more preferably 100 parts by weight or more, and is usually contained in an amount of 100,000 parts by weight or less, preferably 10,000 parts by weight or less, and more preferably 5,000 parts by weight or less, with respect to 100 parts by weight of the ultraviolet absorber.

After the preparation of the liquid composition for forming the ultraviolet absorbing layer, the liquid composition is applied onto a predetermined area where the ultraviolet absorbing layer is intended to be formed. Usually, the liquid composition is applied onto a layer (usually, the first electrode or the substrate) to be in contact with the ultraviolet absorbing layer in the organic photovoltaic cell of the present invention. Examples of the coating method of the liquid composition may include coating methods similar to the coating methods of the liquid composition for forming the active layer.

The liquid composition for forming the ultraviolet absorbing layer is applied to form a film comprising the ultraviolet absorber. Thus, after the application of the liquid composition, as necessary, a process such as a process of drying the formed film to remove the solvent is performed, and consequently the ultraviolet absorbing layer is obtained.

### 8. OTHER LAYERS

The organic photovoltaic cell of the present invention may include other layers in addition to the substrate, the first electrode, the second electrode, the active layer, the functional layer, the barrier layer, and ultraviolet absorbing layer as long as the effect of the present invention is not significantly impaired.

The organic photovoltaic cell of the present invention may further include, for example, a water repellent layer on the outermost surface of the organic photovoltaic cell, and an ultraviolet absorbing layer on a position other than the position opposite to the active layer of the first electrode.

### 9. EMBODIMENTS

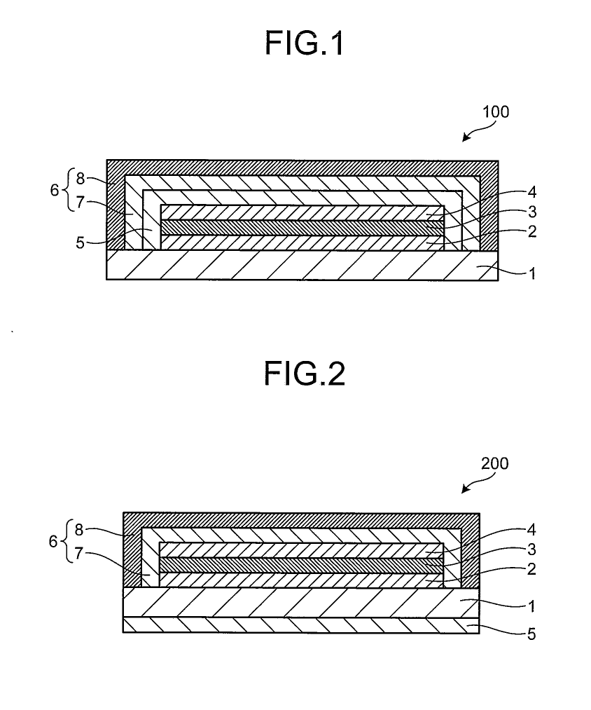

Hereinafter, preferred embodiments of the organic photovoltaic cell of the present invention will be described with reference to drawings. Each of FIG. 1 and

FIG. 2 is a schematic cross-sectional view of the organic photovoltaic cell of the embodiment of the present invention. In the below embodiments, the organic photovoltaic cell will be described while the substrate is placed horizontally.

### 9-1. First Embodiment

An organic photovoltaic cell 100 illustrated in FIG. 1 comprises, on a substrate 1, a first electrode 2, an active layer 3 capable of generating a charge by incident light, and a second electrode 4 in this order. Each of the first electrode 2 and the second electrode 4 is connected with a terminal not illustrated in the schematic for extracting electricity to the exterior. On a surface of the organic photovoltaic cell 100, an ultraviolet absorbing layer 5 and a barrier layer 6 are provided in this order so as to cover the organic photovoltaic cell 100 except the substrate 1. Thus, the organic photovoltaic cell 100 comprises the substrate 1, the first electrode 2, the active layer 3, the second electrode 4, the ultraviolet absorbing layer 5, and the barrier layer 6 in this order.

The barrier layer 6 comprises an inorganic layer 7 comprising an inorganic material and an organic layer 8 formed from an organic material in this order from the active layer 3. One or both of the inorganic layer 7 and the organic layer 8 comprise an ultraviolet absorber to be an layer having a function of blocking ultraviolet light.

The organic photovoltaic cell 100 has the structure as described above. When light is applied from above in the drawing, the applied light is input through the barrier layer 6 and the ultraviolet absorbing layer 5 to the active layer 3, thus generating charges in the active layer 3. The charges generated in the active layer 3 are transported to the first electrode 2 and the second electrode 4, and each is extracted through the terminals to the exterior.

The organic photovoltaic cell 100 includes the barrier layer 6 that comprises the inorganic layer 7 and the organic layer 8, and thus can block the penetration of oxygen and water from outside to inside of the organic photovoltaic cell 100, can suppress the damage to the first electrode 2, the active layer 3, the second electrode 4, and the like caused by external force from outside of the organic photovoltaic cell 100, and can suppress the deterioration of the organic materials due to ultraviolet light contained in light applied to the organic photovoltaic cell 100. In the present embodiment, the ultraviolet absorbing layer 5 is provided between the second electrode 4 and the barrier layer 6; thus, the ultraviolet absorbing layer 5 can also suppress the deterioration of the organic materials due to ultraviolet light contained in light applied to the organic photovoltaic cell 100.

Therefore, the organic photovoltaic cell 100 of the present embodiment can be likely to suppress deteriorations of the first electrode 2, the active layer 3, and the second electrode 4 due to oxygen, water, and ultraviolet light as well as can increase the resistance to external force. On this account, the organic photovoltaic cell 100 is an organic photovoltaic cell that can maintain the photovoltaic conversion efficiency for a longer time than that of a conventional organic photovoltaic cell to elongate the lifetime.

In the barrier layer 6 in the organic photovoltaic cell 100 of the present embodiment, even when the position of the inorganic layer 7 is interchanged with that of the organic layer 8, the same effect can be obtained. For the combination of the first electrode 2 and the second electrode 4, the first electrode 2 may be an anode and the second electrode 4 may be a cathode as well as the first electrode 2 may be a cathode and the second electrode 4 may be an anode.

### 9-2. Second Embodiment

An organic photovoltaic cell 200 illustrated in FIG. 2 has the same structure as that of the organic photovoltaic cell 100 of the first embodiment except that the ultraviolet absorbing layer 5 is placed on a undersurface of the substrate 1 on a position opposite to the active layer 3 of the first electrode 2. Thus, the organic photovoltaic cell 200 comprises the ultraviolet absorbing layer 5, the substrate 1, the first electrode 2, the active layer 3, the second electrode 4, and the barrier layer 6 in this order. The inorganic layer 7 and the organic layer 8 in the barrier layer are arranged in the order of the inorganic layer 7 and the organic layer 8 from the active layer 3. One or both of the inorganic layer 7 and the organic layer 8 comprise an ultraviolet absorber to be a layer having a function of blocking ultraviolet light.

The organic photovoltaic cell 200 has the structure as described above. Hence, when light is applied onto the organic photovoltaic cell 200, the applied light is input to the active layer 4, thus generating charges in the active layer 4. The charges are extracted from the first electrode 2 and the second electrode 6 through the terminals to the exterior.

The organic photovoltaic cell 200 includes the barrier layer 6 comprising the inorganic layer 7 and the organic layer 8, and thus can block the penetration of oxygen and water from outside to inside of the organic photovoltaic cell 200 as well as can suppress the damage to the first electrode 2, the active layer 3, the second electrode 4, and the like caused by external force from outside of the organic photovoltaic cell 200. In the present embodiment, when light is applied from above in the drawing, the barrier layer 6 can block ultraviolet light contained in the applied light, while when light is applied from below in the drawing, the ultraviolet absorbing layer 5 can block ultraviolet light contained in the applied light.

Therefore, the organic photovoltaic cell 200 of the present embodiment can be likely to suppress deteriorations of the first electrode 2, the active layer 3, and the second electrode 4 due to oxygen, water, and ultraviolet light as well as can increase the resistance to external force. On this account, the organic photovoltaic cell 200 is an organic photovoltaic cell that can maintain the photovoltaic conversion efficiency for a longer time than that of a conventional organic photovoltaic cell to elongate the lifetime.

In the barrier layer 6 in the organic photovoltaic cell 200 of the present embodiment, even when the position of the inorganic layer 7 is interchanged with that of the organic layer 8, the same effect can be obtained. For the combination of the first electrode 2 and the second electrode 4, the first electrode 2 may be an anode and the second electrode 4 may be a cathode as well as the first electrode 2 may be a cathode and the second electrode 4 may be an anode.

### 10. APPLICATION OF ORGANIC PHOTOVOLTAIC CELL

In the manner described above, photoelectromotive force is generated between the electrodes of the organic photovoltaic cell of the present invention by the irradiation of light such as sunlight. The organic photovoltaic cell of the present invention may be used, for example, as a solar cell using the photoelectromotive force. When the organic photovoltaic cell is used as the solar cell, the organic photovoltaic cell of the present invention is usually used as the solar cell for an organic thin film solar cell. The plurality of solar cells may also be integrated to make a solar cell module (organic thin film solar cell module) to be used as the solar cell module. The organic photovoltaic cell of the present invention has long lifetime as described above; therefore, a solar cell comprising the organic photovoltaic cell of the present invention can be expected to have longer lifetime.

The organic photovoltaic cell of the present invention may also be used as an organic optical sensor. For example, when the organic photovoltaic cell of the present invention is irradiated with light while applying electrical voltage between the electrodes or without the application, a charge is generated. Hence, when the charge is detected as a photocurrent, the organic photovoltaic cell of the present invention can serve as the organic optical sensor. The plurality of organic optical sensors may be integrated to be used as an organic image sensor.

### 11. SOLAR CELL MODULE

When the organic photovoltaic cell of the present invention is used as the solar cell to constitute the solar cell module, the solar cell module may basically have a module structure similar to that of a conventional solar cell module. The solar cell module generally comprises a supporting substrate, such as a metal and ceramics, on which a solar cell is provided. The solar cell is covered with filling resin, protection glass, and the like. Hence, the solar cell can take in light through the side opposite to the supporting substrate. The solar cell module may use a transparent material such as tempered glass as the supporting substrate, on which the solar cell is provided for taking in light through the transparent supporting substrate.

Known examples of the structure of the solar cell module may include module structures such as a superstraight type, a substrate type, and a potting type; and a substrate-integrated module structure used in an amorphous silicon solar cell. The solar cell module using the organic photovoltaic cell of the present invention may appropriately select a suitable module structure depending on an intended purpose, place, environment, and the like.

For example, in the solar cell modules of the superstraight type and the substrate type as typical module structures, the solar cells are arranged at certain intervals between a pair of supporting substrates. One or both of the supporting substrates are transparent and are usually subjected to an anti-reflective treatment. The adjacent solar cells are electrically connected to each other through wiring such as a metal lead and a flexible wire, and an integrated electrode is placed at a periphery of the solar cell module for extracting electric power generated in the solar cell to the exterior.

Between the supporting substrate and the solar cell, a layer of a filler material such as a plastic material including ethylene vinyl acetate (EVA) may be provided as necessary in order to protect the solar cell and to improve the electric current collecting efficiency. The filler material may be previously formed into a film-shape for installing, or a resin may be filled at a desired position and then cured.

When the solar cell module is used at a place where a hard material is not needed for covering the surface, for example, at a place unlikely to suffer from impact from outside, one of the supporting substrate may not be provided. However, the surface without the supporting substrate of the solar cell module preferably has a surface protection layer by, for example, being covered with a transparent plastic film or being covered with a filler resin to be cured for imparting a protection function.

The periphery of the supporting substrate is usually fixed with a metal frame while interposing the solar cell module in order to seal the inside and to secure rigidity of the solar cell module. A space between the supporting substrate and the frame is usually sealed with a sealing material.

The solar cell module can be used while utilizing the advantages of the organic photovoltaic cell because the solar cell module comprises the organic photovoltaic cell of the present invention that is a photovoltaic cell using an organic material. For example, the organic photovoltaic cell can be formed as a flexible cell, and thus when flexible materials are used for the supporting substrate, the filler material, the sealing material, and the like, a solar cell module can be provided on a curved surface.

The organic photovoltaic cell can be produced using a coating method at low cost, and hence the solar cell module can also be produced using the coating method. For example, when a solar cell module is produced using a flexible support such as a polymer film as the supporting substrate, a solar cell is sequentially formed using the coating method and the like while feeding the flexible support from a roll flexible support, the flexible support is cut into a desired size, and a peripheral part of the cut out piece is sealed with a flexible and moisture-proof material to produce a body of the solar cell module. For example, a solar cell module having a module structure so-called “SCAF” described in “Solar Energy Materials and Solar Cells, 48, pp. 383-391” can also be obtained. The solar cell module using the flexible support may also be bonded and fixed to curved surface glass and the like to be used.

### EXAMPLES

Hereinafter, the present invention will be specifically described with reference to examples, but the present invention is not limited to the examples described below, and any changes and modifications may be made in the present invention without departing from the gist of the present invention.

[Evaluation Method]

In Examples and Comparative Examples described below, a square organic photovoltaic cell having a size of 2 mm×2 mm was produced. For the produced organic photovoltaic cell, using CEP-2000 spectral response measurement system manufactured by Bunkoukeiki Co., Ltd., DC voltage application with respect to the cell was swept at a constant rate of 20 mV/second to determine a short circuit current, an open end voltage, and a fill factor (hereinafter, appropriately abbreviated as “FF”), and the determined short circuit current was multiplied by the determined open end voltage and by the determined fill factor to calculate the photovoltaic conversion efficiency.

The produced organic photovoltaic cell was irradiated with sunlight out of doors for 6 hours for an atmospheric exposure test. In the atmospheric exposure test, sunlight was input from the glass substrate side formed with an ITO film to the active layer. After the atmospheric exposure test, the photovoltaic conversion efficiency was determined, and the photovoltaic conversion efficiency measured after the atmospheric exposure test was divided by the photovoltaic conversion efficiency immediately after the production of the organic photovoltaic cell to calculate a photovoltaic conversion efficiency retention.

### Example 1

A glass substrate patterned with an ITO film having a film thickness of about 150 nm as the first electrode by a sputtering method was prepared. The prepared glass substrate was washed with an organic solvent, an alkaline detergent, and ultrapure water, then dried, and subjected to ultraviolet light-ozone treatment (UV-O₃ treatment) with an UV-O₃ apparatus.

A suspension of poly(3,4-ethylenedioxythiophene)/poly(styrene sulfonate) (manufactured by H.C. Starck-V TECH Ltd., Bytron P TP AI 4083) was prepared and filtered with a filter having a pore size of 0.5 μm. The filtered suspension was applied onto a surface formed with the ITO film on the glass substrate by spin coating to form a film having a thickness of 70 nm. Then, the film was dried in the atmosphere on a hot plate at 200° C. for 10 minutes to form a functional layer.

Next, an ortho-dichlorobenzene solution comprising a macromolecular compound A being an alternating polymer that was obtained by copolymerization of the monomer represented by Formula (3) and the monomer represented by Formula (4) and that had the repeating unit represented by Formula (5) and [6,6]-phenyl-C₆₁-butyric acid methyl ester (hereinafter, appropriately abbreviated as “[6,6]-PCBM”) at a weight ratio 1:3 was prepared. The macromolecular compound A was 1% by weight with respect to ortho-dichlorobenzene. Then, the solution was filtered with a filter having a pore size of 0.5 μm. The obtained filtrate was applied onto the functional layer by spin coating and then was dried in a N₂ atmosphere. Consequently, an active layer having a thickness of 100 nm was obtained. The macromolecular compound A had the weight-average molecular weight of 17,000 in terms of polystyrene and had the number-average molecular weight of 5,000 in terms of polystyrene. The macromolecular compound A had an optical absorption edge wavelength of 925 nm.

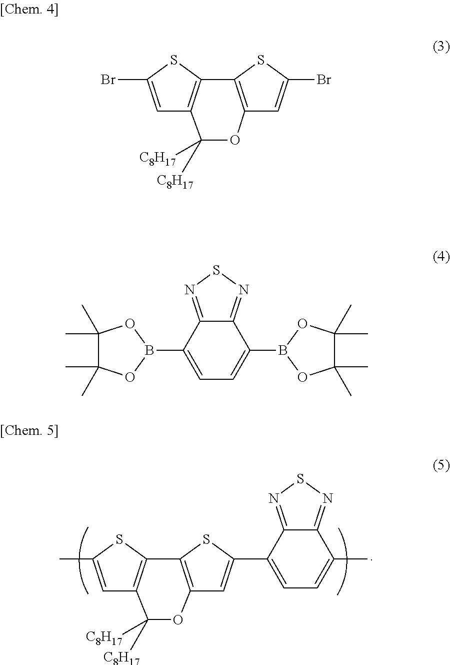

On the active layer, a LiF film having a thickness of about 2.3 nm was formed in a resistance heating deposition apparatus to form a functional layer, and an Al film having a thickness of about 70 nm was subsequently formed to form an electrode.

A dispersion liquid dispersing rutile type titanium dioxide particles (SCR-100C, Sakai Chemical Industry Co., Ltd.) in a dispersant (acetic acid) was prepared. The prepared dispersion liquid was applied onto the electrode composed of Al by a spin coating method and dried at room temperature to form an inorganic layer having a thickness of 70 nm. The obtained inorganic layer was a layer having a function of blocking light having a wavelength of 411 nm or smaller.

On the inorganic layer, a coating agent for blocking ultraviolet light (trade name: UV-G13) manufactured by Nippon Shokubai Co., Ltd. was applied so as to have a thickness of 6 μm and consequently a first organic layer was obtained.

Onto the first organic layer, an epoxy sealant was applied to form a second organic layer.

The barrier layer of the present invention was composed of the inorganic layer, the first organic layer, and the second organic layer.

Onto a surface opposite to an ITO film on the glass substrate with the ITO film, a coating agent for blocking ultraviolet light (trade name: UV-G13) manufactured by Nippon Shokubai Co., Ltd. was applied as the ultraviolet absorbing layer so as to have a thickness of 6 μm; consequently, an ultraviolet absorbing layer was formed.

In this manner, an organic photovoltaic cell comprising the ultraviolet absorbing layer, the glass substrate, the first electrode, the functional layer, the active layer, the functional layer, the second electrode, and the barrier layer having the inorganic layer, the first organic layer, and the second organic layer in this order was obtained.

### Example 2

An organic photovoltaic cell was obtained in the same manner as in Example 1 except that the active layer was formed in the manner described below.

The active layer was formed as follows. First, an ortho-dichlorobenzene solution containing poly(3-hexylthiophene) (hereinafter, appropriately abbreviated as “P3HT”) and [6,6]-PCBM at a weight ratio of 1:0.8 was prepared. P3HT was 1% by weight with respect to ortho-dichlorobenzene. Then, the solution was filtered with a filter having a pore size of 0.1 μl. The obtained filtrate was applied onto the functional layer by spin coating and then dried in a N₂ atmosphere. Hence, an active layer having a thickness of 100 nm was obtained.

### Reference Example 1

An organic photovoltaic cell was produced in the same manner as in Example 1 except that the inorganic layer and the first organic layer were not formed.

### Reference Example 2

An organic photovoltaic cell was produced in the same manner as in Example 2 except that the inorganic layer and the first organic layer were not formed.

### Comparative Example 1

An organic photovoltaic cell was produced in the same manner as in Example 1 except that the ultraviolet absorbing layer, the inorganic layer, and the first organic layer were not formed.

### Comparative Example 2

An organic photovoltaic cell was produced in the same manner as in Example 2 except that the ultraviolet absorbing layer, the inorganic layer, and the first organic layer were not formed.

[Evaluation Result]

Each organic photovoltaic cell produced in Examples 1 and 2 was able to suppress the reduction amount of the photovoltaic conversion efficiency that was reduced with time during the atmospheric exposure test as compared with each organic photovoltaic cell produced in Comparative Examples 1 and 2. That is, each organic photovoltaic cell of Examples 1 and 2 had a longer lifetime than that of each organic photovoltaic cell of Comparative Examples 1 and 2. Furthermore, each organic photovoltaic cell of Examples 1 and 2 showed a higher photovoltaic conversion efficiency retention than those of Reference Examples 1 and 2. That is, each organic photovoltaic cell of Examples 1 and 2 had a longer lifetime than that of each organic photovoltaic cell of Reference Examples 1 and 2.

TABLE 1

| | | | Reference | Reference | Comparative | Comparative |
|---|---|---|---|---|---|---|
| | Example | Example | Example | Example | Example | Example |
| | 1 | 2 | 1 | 2 | 1 | 2 |
| Photovoltaic | 87.53 | 55.04 | 69.08 | 40.08 | 25.37 | 28.93 |
| Conversion | | | | | | |
| Efficiency | | | | | | |
| Retention | | | | | | |
| [%] | | | | | | |

### INDUSTRIAL APPLICABILITY

The organic photovoltaic cell of the present invention can be used as, for example, a solar cell and a photosensor.

1. An organic photovoltaic cell comprising:
a first electrode;
an active layer capable of generating a charge by incident light;
a second electrode; and
a barrier layer, in this order, wherein
the barrier layer comprises an inorganic layer comprising an inorganic material and an organic layer comprising an organic material; and
one or both of the inorganic layer and the organic layer have a function of blocking ultraviolet light.

2. The organic photovoltaic cell according to claim 1, wherein the organic photovoltaic cell further comprises an ultraviolet absorbing layer, and
the active layer, the first electrode, and the ultraviolet absorbing layer are arranged in this order.

3. The organic photovoltaic cell according to claim 1, wherein the barrier layer comprises the inorganic layer and the organic layer in this order from the second electrode.

4. The organic photovoltaic cell according to claim 2, wherein the barrier layer comprises the inorganic layer and the organic layer in this order from the second electrode.
